(19) United States
(12) Patent Application Publication
(10) Pub. No.: US 2016/0209312 A1
(43) Pub. Date: Jul. 21, 2016

(54) RHEOLOGICAL MEASUREMENT DEVICES

(71) Applicants: Tiomothy Ian BROX, Mt. Cook, Wellington (NZ); Petrik GALVOSAS, Karori, Wellington (NZ); VICTORIA LINK LIMITED, Kelburn Wellington (NZ)

(72) Inventors: Timothy Ian BROX, Mt. Cook, Wellington (NZ); Petrik GALVOSAS, Karori, Wellington (NZ)

(73) Assignee: VICTORIA LINK LIMITED, Kelburn, Wellington (NZ)

(21) Appl. No.: 14/915,123

(22) PCT Filed: Aug. 12, 2014
(86) PCT No.: PCT/NZ2014/000167

§ 371 Date: Feb. 26, 2016

(30) Foreign Application Priority Data
Aug. 28, 2013 (NZ) 614797

(51) Int. Cl. G01N 11/14; G01R 33/30; G01N 24/08

(52) U.S. Cl. CPC G01N 11/14; G01N 24/08; G01R 33/307

(57) ABSTRACT

The invention relates to a rheology unit for use in rheology and in Rheo-NMR. The rheology unit has a drive shaft unit that is adapted to attach to an analysis device via a threaded connection to substantially minimise or eliminate mechanical backlash between the drive shaft unit and analysis device

### TECHNICAL FIELD The invention relates to rheological measurement devices for use in rheology and in Rheo-NMR.

### BACKGROUND OF THE INVENTION

Nuclear magnetic resonance (NMR) spectroscopy and velocimetry have become unique tools for the investigation of complex fluids under. shear. Past improvements have enriched the information learned about soft matter through Rheo-NMR experiments.

Rheo-NMR is the study of rheology using NMR methods and is primarily used for soft matter research. Rheo-NMR provides the ability to study materials under shear that are optically opaque and allows behaviours, such as slip, shear thinning, shear banding, yield stress behaviour, nematic director alignment, and shear-induced mesophase reorganisation, to be identified and analysed.

Devices currently used in NMR machines for Rheo-NMR typically comprise a drive shaft to which an analysis device (such as a shear cell or Couette cell) can be attached. The analysis device is for containing the sample under study to be analysed using the NMR machine. A motor is mounted separately to the drive shaft and is connected to the drive shaft to cause the drive shaft to rotate along its axle. A controller is used to set the speed at which the motor rotates.

However, commercially available Rheo-NMR systems have significant limitations on the type and resolution of analysis that can be undertaken. In known Rheo-NMR practices, a drive shaft is mounted within the NMR magnet and a shear cell, such as a Couette, is fitted to the drive shaft within the machine. To attach the Couette to the drive shaft, a pin is located through aligned apertures in the drive shaft and Couette. However, to allow the Couette to be attached to the drive shaft relatively easily, the apertures are significantly larger than the diameter of the pin. This means that as the drive shaft rotates, there is a time delay before the pin engages with the Couette to cause the Couette to rotate. This time delay is referred to as mechanical backlash or mechanical slop, which means that it is not possible to continue analysing the sample accurately when the direction of rotation of the drive shaft changes, thus limiting the range of possible experiments to those relating to a constant shear rate in a single direction.

Known Rheo-NMR devices do not enable the measurement of properties of a sample material under oscillatory flow.

It is therefore an object of the invention to provide a Rheo-NMR device that goes at least some way toward overcoming one or more disadvantages of the prior art, or to at least provide a useful alternative to existing Rheo-NMR devices.

### SUMMARY OF THE INVENTION

In a first aspect, the invention provides a rheology unit comprising a drive shaft unit comprising: a two part drive shaft comprising a primary shaft having a first end and a second end, and an extension shaft having a first end and a second end, the first end of the extension shaft being coupled to the second end of the primary shaft; a two part drive shaft housing for housing the drive shaft, the drive shaft housing comprising a primary housing having a first end and a second end and an extension housing also having a first end and a second end, wherein the first end of the extension housing is attached to the second end of the primary housing; a motor for rotating the drive shaft within the drive shaft housing; a positioning sensor for sensing the position of the drive shaft relative to the drive shaft housing; and a control system for controlling the speed, frequency, and/or direction of rotation of the drive shaft; wherein the extension shaft is concentrically supported within the extension housing and the extension housing is adapted to attach to an analysis device through a threaded connection that allows the analysis device to substantially align with the drive shaft housing.

Preferably, the motor is a servo-stepper motor that is connected to the first end of the drive shaft.

Preferably, the positioning sensor is an optical encoder. Preferably, the drive shaft unit further comprises a collar that clamps around a portion of the drive shaft housing and is adapted to control the depth at which the rheology unit can be fitted within a bore of an NMR machine.

Preferably, the drive shaft unit is attached to an analysis device for holding a sample material to be analysed in rheo-NMR experiments.

Preferably, the analysis device comprises a cell coupler adapted to attach the analysis device to the drive shaft unit, the cell coupler having a threaded first end that meshes with a threaded second end of the extension housing.

Preferably, the analysis device comprises a spindle that is coupled to the extension shaft to cause the spindle and extension shaft to rotate simultaneously.

Preferably, the analysis device is any one of: a cylindrical Couette cell; a rotating outer wall Couette cell; a cone-plate shear cell; and a plate-plate shear cell.

In a second aspect, the invention provides an analysis device for attaching to the drive shaft of the rheology unit of the first aspect of the invention, the device comprising a cell coupler having a threaded first end that meshes with a threaded second end of the extension housing to attach the analysis device to the drive shaft unit.

In one form, the analysis device comprises a cylindrical Couette cell further comprising a spindle, a cylindrical bob, a bottom cap, and an outer tube, wherein the spindle is adapted to attach the bob to the drive shaft of the drive shaft unit and wherein the bob is positioned substantially concentrically within the outer tube, which comprises a first end that is attached to the cell coupler and a second end that is attached to the bottom cap, wherein a cavity is formed between the bob and the outer tube within which a sample material may be held.

Preferably, the bob comprises a first end that is attached to the spindle and a second end that projects into the outer tube, the second end comprising an interior cavity in which a fluid can be held.

In another form, the analysis device comprises a rotating outer wall Couette cell comprising an inner wall and an outer wall and a gap between the inner and outer walls for holding a sample material therein, wherein the outer wall is adapted to rotate when the analysis device is attached to the drive shaft unit of the rheology unit.

Preferably, the rotating outer wall Couette cell further comprises a spindle, a bottom cap, and an outer tube, wherein the inner wall is formed by a second end of the cell coupler and the outer wall is formed by the outer tube, wherein a first end of the spindle is connected to the drive shaft to rotate the spindle and a second end of the spindle is attached to the bottom cap, and wherein a second end of the outer tube is also attached to the bottom cap to cause the outer tube to rotate simultaneously with the drive shaft.

Preferably, a spacer is used on the first end of the outer tube to keep the outer tube concentric with the inner wall.

Preferably, the rotating outer wall Couette cell further comprises an alignment collar attached to the cell coupler and adapted to position the second end of the cell coupler concentrically within the outer tube.

In another form, the analysis device comprises a cone-plate shear cell, the shear cell further comprising a coupler shaft and spindle, the coupler shaft being adapted to attach the spindle to the drive shaft of the drive shaft unit, an outer tube within which the spindle is concentrically located, the outer tube comprising a first end attached to a top cap attached to the cell coupler and a second end attached to a bottom cap, wherein the device further comprises a lower plate supported by the bottom cap, and a cone that is attached to the spindle to rotate simultaneously with the drive shaft.

In yet another form, the analysis device comprises a plate-plate shear cell, the shear cell further comprising a coupler shaft and spindle, the coupler shaft being adapted to attach the spindle to the drive shaft of the drive shaft unit, an outer tube within which the spindle is concentrically located, the outer tube comprising a first end attached to a top cap attached to the cell coupler and a second end attached to a bottom cap, wherein the device further comprises a lower plate supported by the bottom cap, and an upper plate that is attached to the spindle to rotate simultaneously with the drive shaft.

Preferably, the outer tube of the analysis devices is transparent glass or plastic.

Any reference to prior art documents in this specification is not to be considered an admission that such prior art is widely known or forms part of the common general knowledge in the field.

The term ‘drive shaft’ as used in this specification, should be interpreted to include a single shaft or a series of substantially aligned shafts that engage with a motor at a first end and with an analysis device at a second end to cause at least part of the analysis device to rotate as the motor causes the drive shaft to rotate. Similarly, the term ‘drive shaft housing’ as used in this specification, should be interpreted to include a single part drive shaft housing or a series of substantially aligned drive shaft housings, the housing or series of housings having a first end that attaches to the motor mount and a second end that attaches to an analysis device.

The term ‘in line coupling’ in this specification, should be interpreted to mean a coupling that connects one part with another part, even if the parts are slightly misaligned, so that as one of the parts rotates, the other part is caused to rotate substantially simultaneously.

As used in this specification, the words ‘comprises’, ‘comprising’, and similar words, are not to be interpreted in an exclusive or exhaustive sense. In other words, they are intended to mean ‘including, but not limited to’.

### BRIEF DESCRIPTION OF THE FIGURES

Preferred forms of the invention will now described in relation to the accompanying drawings, in which:

FIG. 1 is an exploded view of a rheology unit according to one form of the invention;

FIG. 2a is a perspective view of a drive shaft unit according to one form of the invention;

FIG. 2b is a side view of the drive shaft of FIG. 2a;

FIG. 2c is a cross-sectional side view of the drive shaft taken along lines A-A of FIG. 2b;

FIG. 3 is an exploded view of the drive shaft of FIG. 2a;

FIG. 4a is a perspective view of the motor mount for the drive shaft unit of FIG. 2a;

FIG. 4b is a side view of the motor mount of FIG. 4a;

FIG. 4c is a cross-sectional side view of the motor mount taken along lines A-A of FIG. 4b;

FIG. 5a is a perspective view of the housing collar for the drive shaft unit of FIG. 2a;

FIG. 5b is a side view of the housing collar of FIG. 5a;

FIG. 5c is another side view of the housing collar of FIG. 5a;

FIG. 6 is a perspective view of the drive shaft for the drive shaft unit of FIG. 2a;

FIG. 7a is a perspective view of the drive shaft housing for the drive shaft unit of FIG. 2a;

FIG. 7b is a side view of the drive shaft housing of FIG. 7a;

FIG. 7c is a cross-sectional side view of the drive shaft housing taken along lines A-A of FIG. 7b;

FIG. 8a is a perspective view of the extension housing for the drive shaft unit of FIG. 2a;

FIG. 8b is a side view of the extension housing of FIG. 8a;

FIG. 8c is a cross-sectional side view of the extension housing taken along lines A-A of FIG. 8b;

FIG. 9 is a side view of the extension shaft for the drive shaft unit of FIG. 2a;

FIG. 10 is an exploded view of an analysis device in the form of cylindrical Couette cell according to the invention;

FIG. 11a is a perspective view of the analysis device of FIG. 10 Figure lib is a side view of the Couette cell of FIG. 11a;

FIG. 11c is a cross-sectional side view of the Couette cell taken along lines A-A of FIG. 11b;

FIG. 12a is a perspective view of a cell coupler to couple the Couette cell to the drive shaft unit;

FIG. 12b is a side view of the cell coupler of FIG. 11a;

FIG. 12c is a cross-sectional side view of the cell coupler taken along lines A-A of FIG. 12b;

FIG. 13a is a perspective view of a spindle for the Couette cell of FIG. 10;

FIG. 13b is a side view of the spindle of FIG. 13a;

FIG. 13c is another side view of the spindle of FIG. 13a;

FIG. 14a is a perspective view of a bob for the Couette cell of FIG. 10;

FIG. 14b is a side view of the bob of FIG. 14a;

FIG. 14c is a cross-sectional side view of the bob taken along lines A-A of FIG. 14b;

FIG. 15a is a perspective view of a bottom cap for the Couette cell of FIG. 10;

FIG. 15b is a side view of the bottom cap of FIG. 15a;

FIG. 15c is a cross-sectional side view of the bottom cap taken along lines A-A of FIG. 15b;

FIG. 15d is another side view of the bottom cap of FIG. 15a;

FIG. 15e is a cross-sectional side view of the bottom cap taken along lines B-B of FIG. 15d;

FIG. 15f is a top view of the spindle of FIG. 15a;

FIG. 16 is a perspective view of an outer tube for the Couette cell of FIG. 10;

FIG. 17 is an exploded view of a rotating outer wall cylindrical Couette cell according to the invention;

FIG. 18a is a perspective view of the assembled rotating outer wall Couette cell of FIG. 17;

FIG. 18b is a side view of the Couette cell of FIG. 18a;

FIG. 18c is a cross-sectional side view of the Couette cell taken along lines A-A of FIG. 18b;

FIG. 19a is a perspective view of a cell coupler for the Couette cell of FIG. 17;

FIG. 19b is a side view of the cell coupler of FIG. 19a;

FIG. 19c is a cross-sectional side view of the cell coupler taken along lines A-A of FIG. 19b;

FIG. 20a is a perspective view of an alignment collar for the Couette cell of FIG. 17;

FIG. 20b is a side view of the alignment collar of FIG. 20a; p FIG. 20c is a cross-sectional side view of the alignment collar taken along lines A-A of FIG. 20b;

FIG. 21a is a perspective view of a spindle and bottom cap in combination for the Couette cell of FIG. 17;

FIG. 21b is a side view of the spindle and bottom cap of FIG. 21a;

FIG. 22 is a perspective view of a outer tube for the Couette cell of FIG. 17;

FIG. 23 is an exploded view of a plate-plate analysis device according to the invention;

FIG. 24a is a perspective view of the plate-plate analysis device of FIG. 23;

FIG. 24b is a side view of the plate-plate analysis device of FIG. 24a;

FIG. 24c is a cross-sectional side view of the plate-plate analysis device taken along lines A-A of FIG. 24b;

FIG. 25a is a perspective view of a cell coupler for the plate-plate analysis device of FIG. 22;

FIG. 25b is a side view of the plate-plate analysis device of FIG. 25a;

FIG. 25c is a cross-sectional side view of the plate-plate analysis device of FIG. 25b;

FIG. 25d is another side view of the plate-plate analysis device of FIG. 25a;

FIG. 26a is a perspective view of a coupler shaft for the plate-plate analysis of FIG. 22;

FIG. 26b is a side view of the coupler shaft of FIG. 26a;

FIG. 27a is a perspective view of a spindle for the plate-plate analysis device of FIG. 23;

FIG. 27b is a side view of the spindle of FIG. 27a;

FIG. 28a is a perspective view of a top cap for the plate-plate analysis of FIG. 23;

FIG. 28b is a side view of the top cap of FIG. 28a;

FIG. 28c is a cross-sectional side view taken along lines A-A of FIG. 28b;

FIG. 28d is another side view of the top cap of FIG. 28a;

FIG. 29a is a perspective view of a top plate for the plate-plate analysis device of FIG. 23;

FIG. 29b is a side view of the top plate of FIG. 29a;

FIG. 29c is a cross-sectional side view taken along lines A-A of FIG. 29b;

FIG. 30a is a perspective view of an outer tube for the plate-plate analysis device of FIG. 23;

FIG. 30b is a side view of the outer tube of FIG. 30a;

FIG. 31a is a perspective view of a bottom cap for the plate-plate analysis device of FIG. 23;

FIG. 31b is a side view of the bottom cap of FIG. 31a;

FIG. 31c is a cross-sectional side view of the bottom cap taken along lines A-A of FIG. 30b;

FIG. 32a is a perspective view of a bottom plate for the plate-plate analysis device of FIG. 23; and

FIG. 32b is a side view of the bottom plate of FIG. 32a.

### DETAILED DESCRIPTION

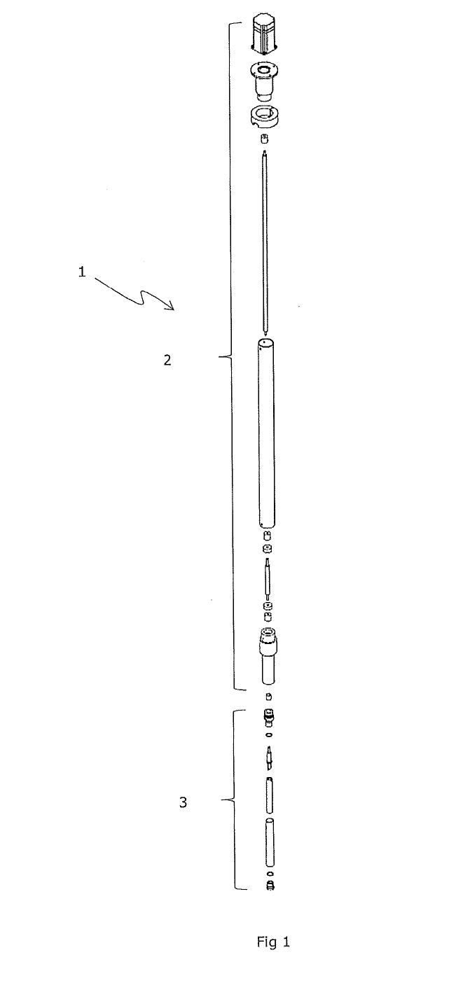

The invention relates to a rheology unit for measuring rheology samples within an NMR machine using a high field (approximately 250 MHz or greater) super conducting NMR magnet. As shown in FIG. 1, the rheology unit 1 comprises a drive shaft unit 2 and an analysis device 3, such as a shear cell, that is attached to the drive shaft unit.

The drive shaft and analysis device are preferably adapted so that they can be attached together outside an NMR machine to form the rheology unit. The rheology unit is then placed within the machine to analyse a sample held within the analysis device. The rheology unit is adapted so that the analysis device can be attached to the drive shaft unit in a way that at least minimises or substantially eliminates mechanical backlash between the drive shaft and the analysis device.

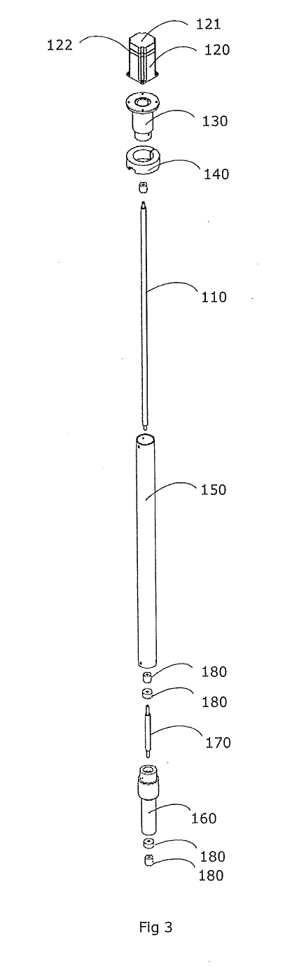

As shown in FIGS. 1, 2a to 2c, and 3, the drive shaft unit comprises a drive shaft 110, which is driven by a motor 120 having an output shaft connected to a first end of the drive shaft via a coupling. The motor is preferably connected to a control system 121 that controls the speed, frequency and/or direction of rotation of the output shaft of the motor. The motor can therefore cause the drive shaft to rotate clockwise and anti-clockwise (as desired) along the longitudinal axis of the drive shaft at various speeds and frequency of rotation. At its opposing second end, the drive shaft is attached to an analysis device.

The motor may be a servo motor, a stepper motor, a servo-stepper motor, or any other suitable motor. In one form, the motor is a dual shaft stepper motor having a first shaft that is coupled to the drive shaft and a second shaft that is attached to a positioning sensor 122, such as a high resolution optical encoder, that reads the orientation of the drive shaft in relation to a drive shaft housing. The positioning sensor, or optical encoder, communicates this information to the motor control system 121. If necessary, the control system can adjust the motor speed, frequency, and/or direction of rotation of the drive shaft. The positioning sensor, motor, and control system provide a closed feedback loop that allows for prompt and accurate adjustment of the rotational speed, frequency and direction of the drive shaft to satisfy the operating criteria that are pre-programmed into the control system. In this way, it is possible to ensure that the drive shaft is in the correct position relative to the drive shaft housing at set time intervals to suit the parameters of the experiment.

Where a stepper motor is used, fine rotational control is also provided for. For example, tests have shown that, using feedback from a high resolution optical encoder, the stepper motor can be programmed to rotate the drive shaft in 0.05⁰ steps.

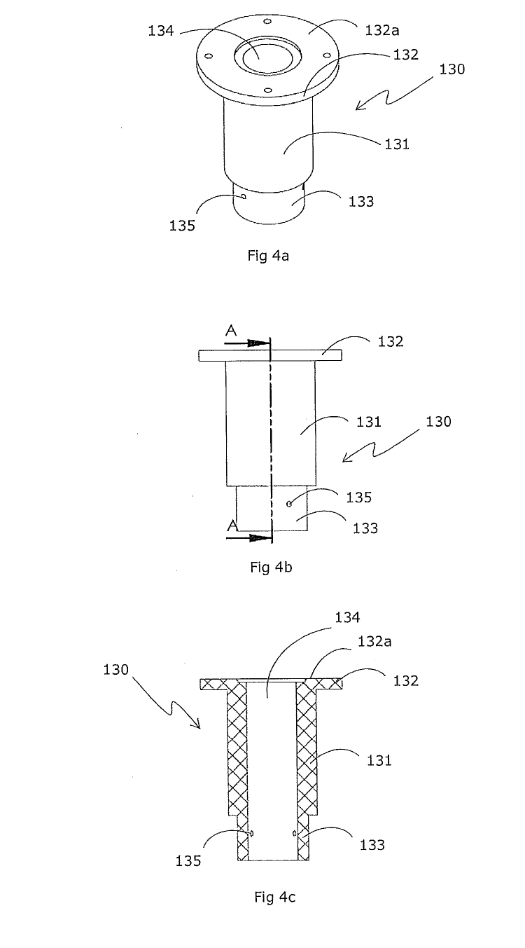

In one form, the motor 120 is mounted on a motor mount 130 that is attached to a drive shaft housing within which the drive shaft is positioned. In one form, as shown in FIGS. 4a to 4c, the motor mount 130 comprises a cylindrical body 131 having a flanged collar 132 at its first end. The flanged collar 132 comprises a first face 132a on which the motor 120 is mounted. In one embodiment, the opposing second end of the motor mount comprises a cylindrical block 133 that projects from the motor mount body 131 and preferably comprises a pair of threaded apertures 135. A centrally located bore 134 extends through the motor mount.

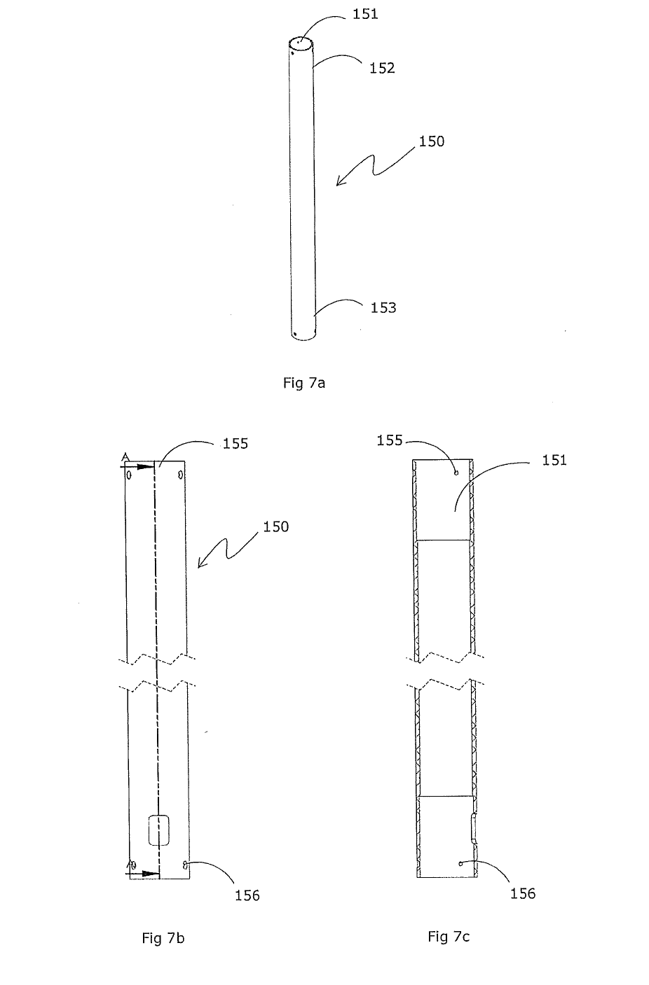

The second end of the motor mount is adapted to attach to the substantially cylindrical drive shaft housing 150, shown in FIGS. 7a to 7c. The drive shaft housing 150 has a central bore that is substantially concentrically aligned with the central bore 134 of the motor mount. In one form, the cylindrical block 133 fits within a first end 152 of the bore of the drive shaft housing and is positioned so that the apertures 135 of the motor mount align with apertures 155 formed at the first end of the drive shaft housing. Screws are placed through the aligned apertures 135, 155 to couple the drive shaft housing to the motor mount. However, the drive shaft housing and motor mount may be attached together in any suitable arrangement. For example, in another form, the first end of the drive shaft housing may be threaded and adapted to mesh with a threaded region provided on the cylindrical block of the motor mount so that the drive shaft housing can be screwed onto the motor mount.

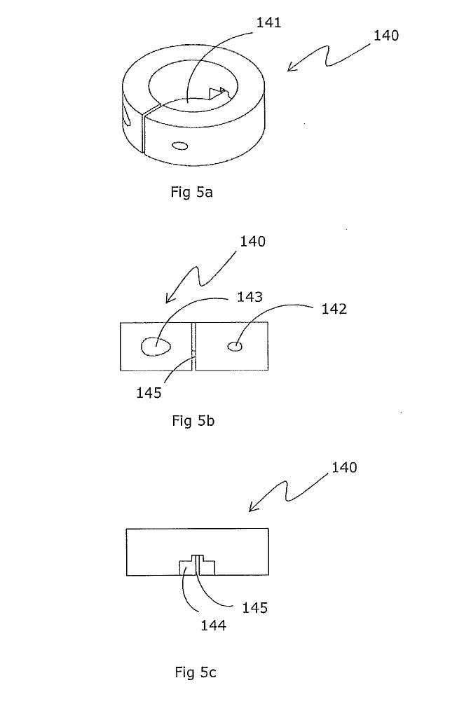

The rheology unit further comprises a housing collar 140 having a substantially ring-shaped body having a slit opening 145 and a pair of substantially opposing threaded apertures 142 and 143 on either side of the slit 145, as shown in FIGS. 5a to 5c. The housing collar 140 comprises a central bore 141 within which the drive shaft housing 150 is located. The housing collar is adapted to substantially surround the drive shaft housing and can slide up and down the drive shaft housing until it reaches a desired position. The slit 145 allows the housing collar to be compressed so that the slit closes and the collar clamps around a portion of the drive shaft housing when the collar is in the desired position. The collar is held in the clamping position by a screw or the like that engages with threaded interiors of the apertures 142 and 143 to hold the collar closed. Alternatively, the collar may be held in the clamping position by any other suitable means.

The collar forms an outwardly projecting lip around the drive shaft housing and is used to set the insertion depth of the drive shaft into the bore of the magnet of an NMR machine. Therefore, by adjusting the position of the collar along the length of the drive shaft housing, it is possible to adjust the depth at which the rheology unit is placed in an NMR machine. The housing collar also comprises a recess 144 that is adapted to mate with one or more projections located in the bore of a typical NMR machine to hold the rheology unit in position within the machine.

As mentioned above, the drive shaft unit also comprises a drive shaft housing. The drive shaft is positioned substantially concentrically within the drive shaft housing.

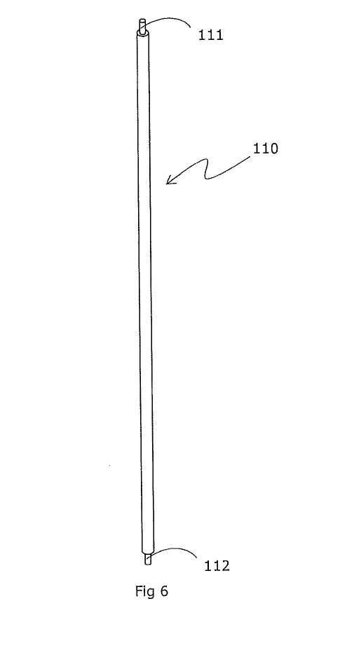

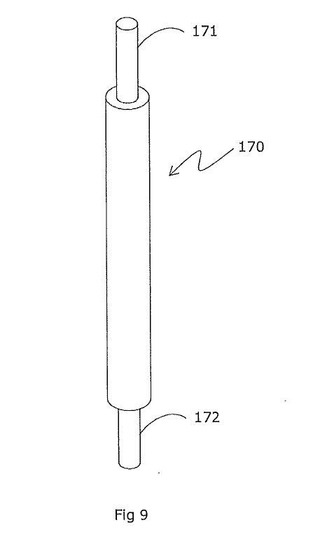

In one form, as shown in FIGS. 6 and 9, the drive shaft comprises two parts: a primary shaft 110 and an extension shaft 170. The two-part drive shaft is located within a drive shaft housing that also comprises two parts: a primary housing 150 and an extension housing 160.

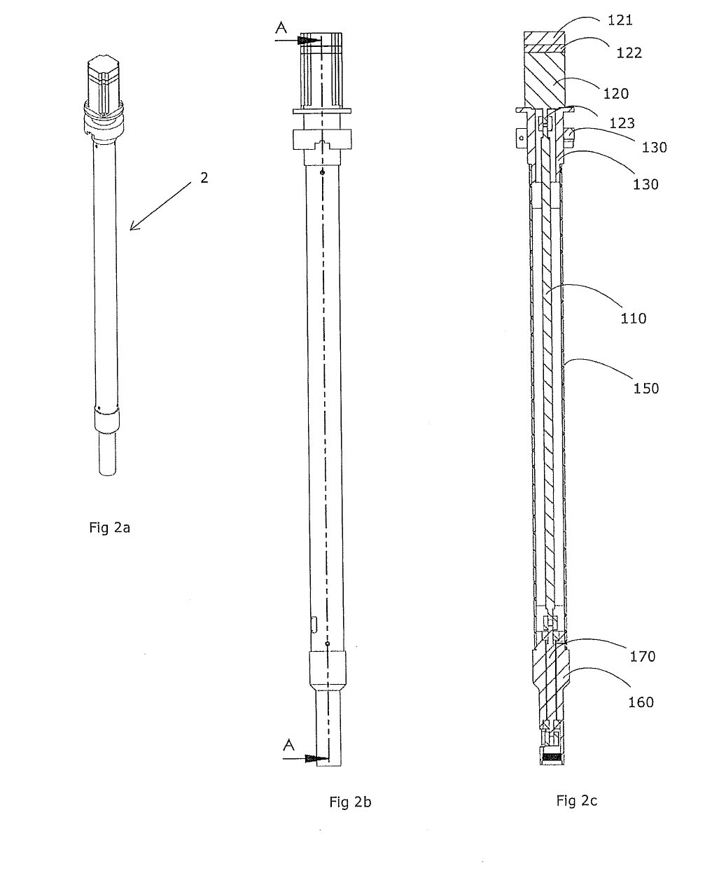

Referring to FIGS. 6 and 9, the primary housing 150 comprises a substantially cylindrical body having opposing first and second ends 152, 153 and a central bore 151 extending along the length of the housing. The primary shaft 110 is located substantially concentrically within the bore of the primary housing so that the first end 111 of the primary shaft is positioned near the first end 152 of the primary housing and the second end 112 of the primary shaft is positioned near the second end 153 of the primary housing, as shown best in FIG. 2c.

The first end of the primary shaft extends beyond the first end of the primary housing 150 and into the central bore of the motor mount 130 to connect to the output shaft 123 of the motor via a coupling 10, as shown in FIG. 1. The output shaft 123 of the motor extends into the central bore 134 of the motor mount from the other direction. Preferably, the drive shaft and motor shaft are coupled together using an inline coupling, although any other suitable coupling could be used to enable the drive shaft to rotate without adversely rubbing against the surface of the motor or motor housing.

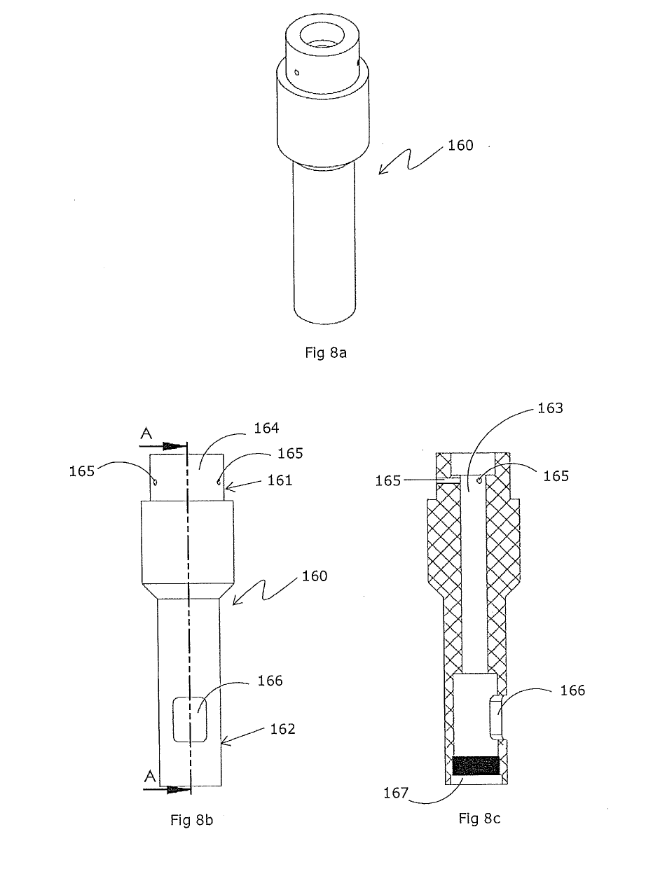

The second end of the primary housing 150 is attached to the extension housing 160, one form of which is shown In FIGS. 8a to 8c. The extension housing 160 also comprises a substantially cylindrical body having a first end 161 and a second end 162. A central bore 163 extends along the length of the extension housing and is adapted to house the extension shaft 170 therein. A plurality of bearings or bushes are provided within the central bore of the extension housing to retain the concentric positioning of the extension shaft within the extension housing.

The extension housing is adapted to attach to the primary housing to form an elongate drive shaft housing. Typically, the extension housing Is screwed onto the primary housing using a threaded connection. In one form, as shown in FIGS. 8a to 8c, the first end 161 of the extension housing 160 comprises a cylindrical block 164 that fits within the bore 151 of the second end 153 of the primary housing 150. A pair of opposing apertures 165 formed on either side of the cylindrical block 164 are aligned with opposing apertures 156 formed on either side of the second end of the primary housing 150. Screws or the like engage with the aligned apertures 165, 156 to couple the primary housing 150 to the extension housing 160 using a threaded connection. However, the extension housing may be attached to the primary housing in any suitable arrangement. For example, the first end of the extension housing may be a threaded end that meshes with and screws onto a threaded second end of the primary housing to attach the primary housing and extension housing together using a threaded connection.

The extension housing is also adapted to attach to an analysis device through a firm connection, such as a threaded connection. In one form, as shown in FIGS. 8a to 8c, the second end 162 of the extension housing 160 comprises a threaded interior surface for meshing with a threaded first end of a cell coupler of an analysis device to attach the analysis device to the drive shaft unit. In this form, the analysis device is screwed onto the threaded second end of the extension housing. An internal collar 167 is provided at the second end of the extension housing to control the depth at which the cell coupler is inserted within the extension housing. Because a portion of the cell coupler is held within the interior bore of the extension housing, the analysis device Is aligned with the extension housing and is prevented from wobbling relative to the extension housing when in use. Therefore, this arrangement creates a precision alignment between the extension housing and the analysis device. In an alternative embodiment, screws or the like may be used to attach an analysis device to the extension housing using a threaded connection. In this arrangement, threaded apertures are provided on the analysis device, the extension housing, or both for meshing with screws extending from the extension housing or analysis device respectively or from both. The meshed threaded regions provide a binding force that holds the two parts together.

The extension shaft 170 is located substantially concentrically within the central bore 161 of the extension housing 160 and substantially in line with the primary shaft 110. As shown in FIG. 9, a first end 171 of the extension shaft is coupled to the second end of the primary shaft 110 via an inline coupling or any other suitable coupling. The second end 172 of the extension shaft connects to a spindle of the analysis device 3 (either directly or via a coupler shaft) so that rotation of the drive shaft causes the spindle to rotate substantially simultaneously, thereby eliminating or at least minimising mechanical backlash.

The distance between the motor and the analysis device can be close to a metre or more due to the length of the drive shaft. Consequently, a long drive shaft is prone to flex as it rotates. Ideally, the analysis device is able to rotate smoothly at a constant speed, but this can be impeded as the drive shaft flexes. One way of allowing the drive shaft to flex without negatively impacting the rotational motion of the analysis device is to use a two-part drive shaft, as described above. The long primary drive shaft is still prone to flex. Therefore, the shorter extension shaft is used to transmit rotational movement from the primary shaft to the analysis device. The rotational movement of the extension shaft is kept smooth (i.e. is not signficantly impacted by the flex of the primary shaft) by the use of bushes 180 or bearings that engage with the extension shaft to form an inline coupling at each end of the extension shaft where the extension is coupled to the drive shaft and to the analysis device. Bushes or bearings are also used to keep the extension shaft concentrically located within the extension housing. In this arrangement, the smooth rotational motion of the extension shaft is imposed on the analysis device.

The analysis device may be any part or arrangement of parts used to hold a sample for analysis by a rheology or NMR machine. For example, the analysis device may be a Couette cell, shear cell, cone-plate device, plate-plate device, or the like. The rheology unit of the invention may be attached to different types of analysis devices. Examples of just some types of analysis devices that can be coupled to the drive shaft unit of the invention will now be described.

### Cylindrical Couette Cell

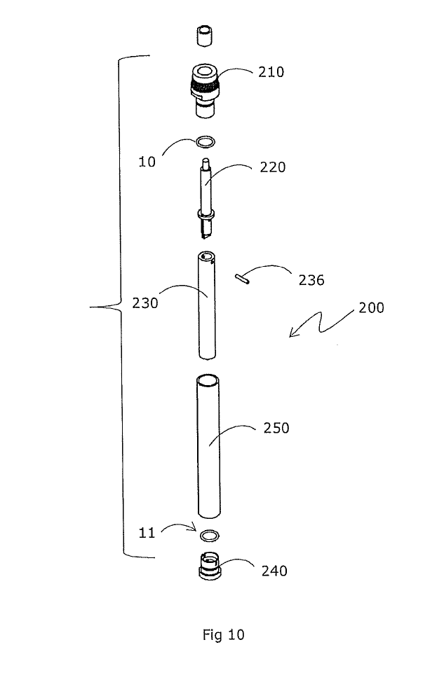

One form of analysis device that can be used in the rheology unit of the invention is a cylindrical Couette cell 200, as shown in FIGS. 10 to 16.

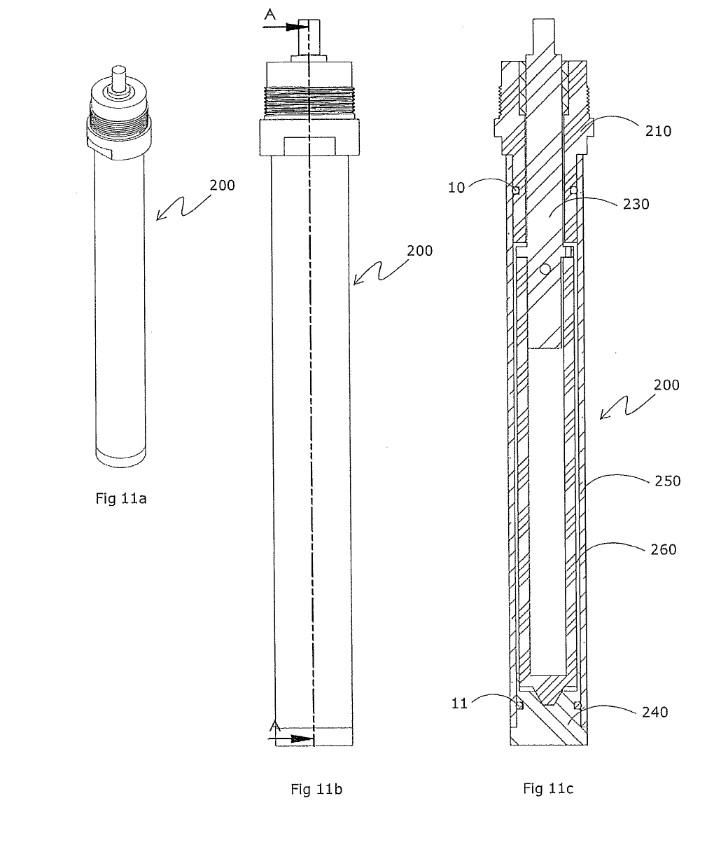

As shown In FIGS. 10 and 11a to 11c, the Couette cell 200 comprises a cell coupler 210 for attaching the Couette cell to the drive shaft unit, a spindle 220, a bob 230, a bottom cap 240, and an outer tube 250.

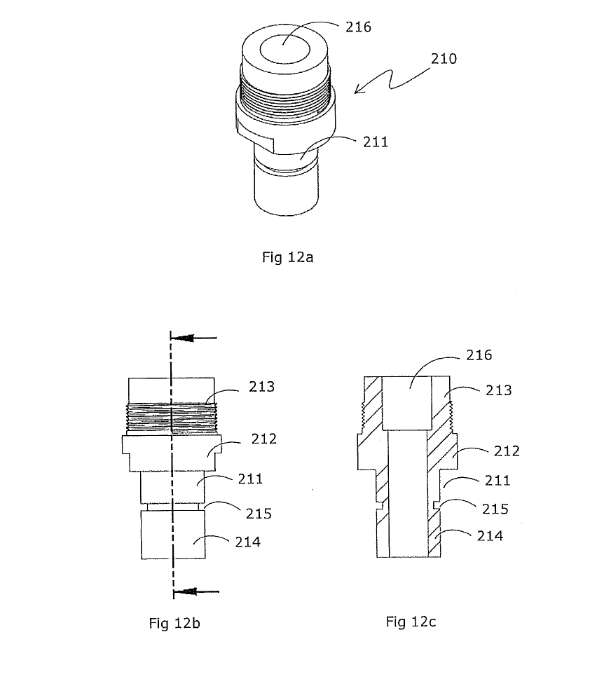

The cell coupler 210 comprises a body 211 having a collar 212 that extends around the circumference of the body and a central bore 216 that extends along the length of the cell coupler, as shown in FIGS. 12a to 12c. When the Couette cell is attached to the drive shaft unit, the central bore of the cell coupler substantially aligns with the central bore of the extension housing. A first end 213 of the cell coupler projects from the collar 212 and has a threaded section for meshing with the threaded second end of the extension housing, as described above. A second end 214 of the cell coupler extends from the opposite end of the coupler body 211 and is adapted to attach the cell coupler to the outer tube 250. In one form, the second end of the cell coupler is located within a first end of the outer tube 250 so that the first end 251 of the outer tube abuts the collar 212 of the cell coupler 210. A channel 215 is formed in the circumference of the cell coupler body and delineates the coupler body from the second end of the cell coupler. A seal, such as an o-ring 10 nests within channel 215 to attach and seal the cell coupler to the outer tube. In one form, the cell coupler comprises gripping surfaces that a wrench or the like can grip onto when attaching and detaching the cell to and from the drive shaft unit.

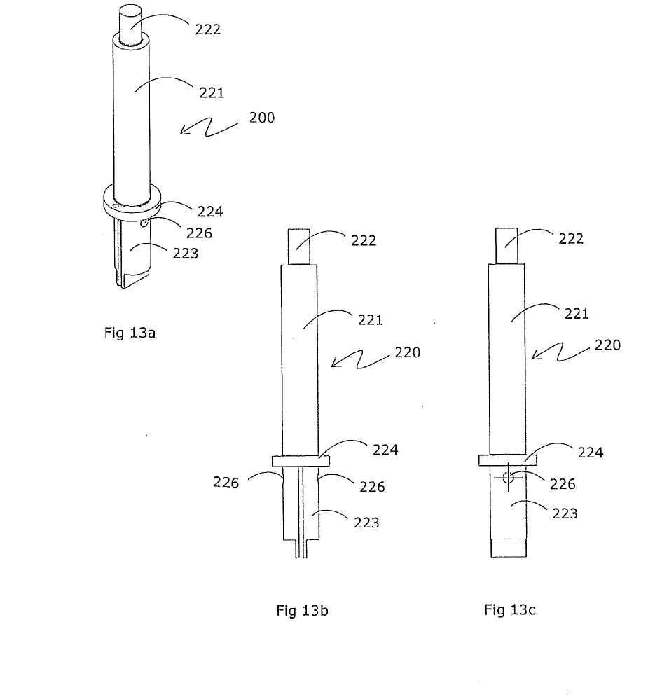

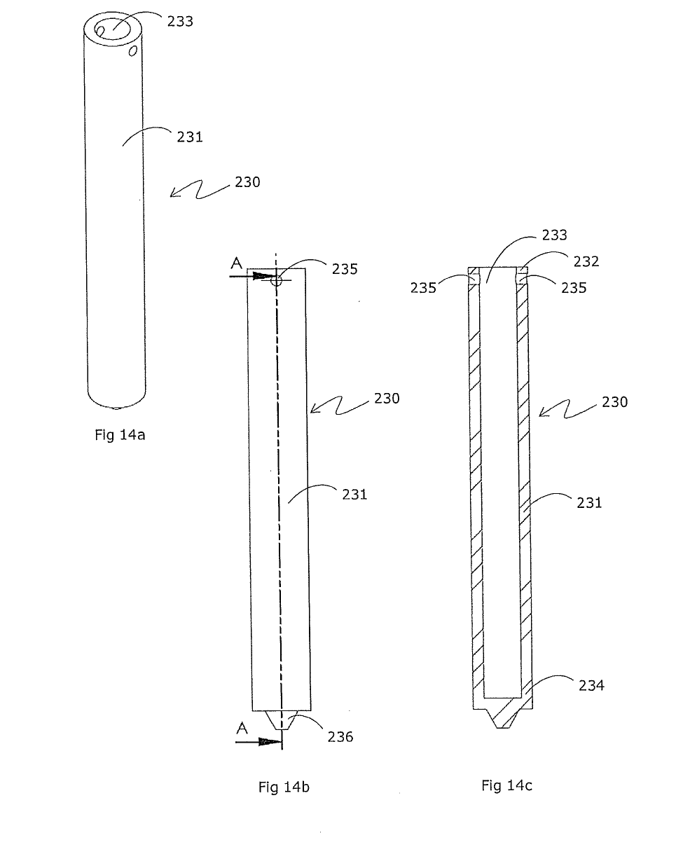

The spindle 220 is positioned within the central bore 216 of the cell coupler. As shown in FIGS. 13a to 13c, the spindle comprises a substantially cylindrical body 221 having a first end 222 that projects from the first end 213 of the cell coupler and is adapted to attach to the second end of the extension shaft 170 via an in line coupling or the like. An opposing second end 223 of the spindle projects from the second end of the cell coupler and attaches to the bob 230. As shown in FIGS. 14a to 14c, the bob 230 comprises a substantially cylindrical body 231 having an open first end 232, a central bore 233, and a closed second end 234. The central bore 233 of the bob is dimensioned to receive the second end 223 of the spindle. A collar 224 is located between the first and second ends of the spindle and extends around the circumference of the spindle body. The collar 224 abuts the first end of the bob to control the depth at which the spindle is positioned within the bore of the bob. In one form, a pair of opposing apertures 226 are formed on the second end of the spindle. The apertures 226 align with corresponding opposing apertures 235 located at a first end 232 of the bob 230 and one or more screws or the like engage with the apertures to attach the spindle to the bob.

An interior cavity may be provided in the second end 223 of the bob and can be filled with fluid. The fluid in the bob moves as a rigid body when the bob is rotated. The fluid is seen via NMR and provides an indication of the rotational speed of the bob.

As mentioned above, the second end 234 of the bob 230 is a closed end. In one form, the second end 234 of the bob comprises a substantially frustoconical tip 236 that is shaped to correspond with a frustoconical recess formed in a first surface 245 of the bottom cap 240, as shown in FIGS. 14b and 14c.

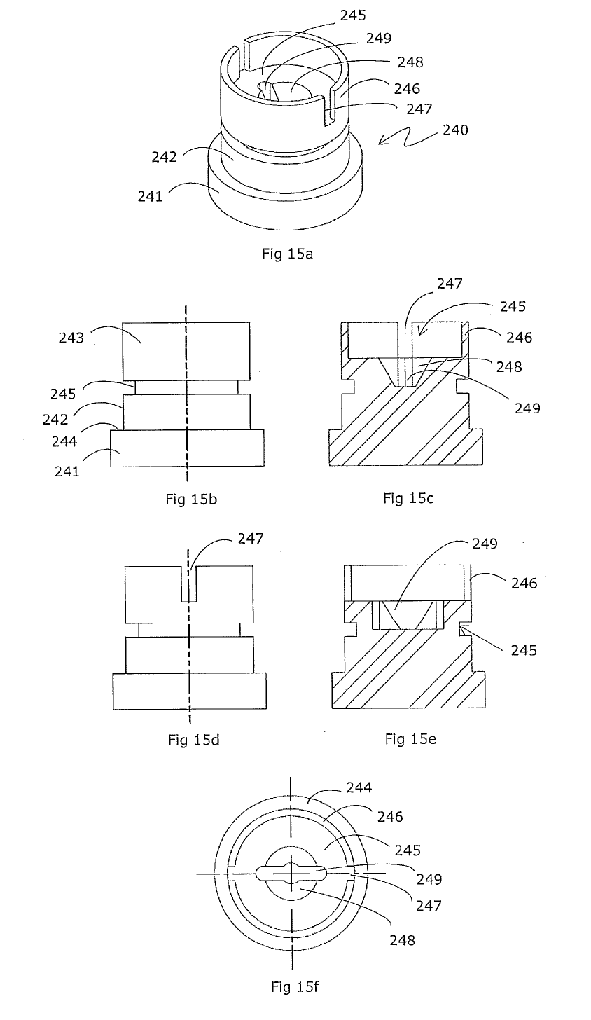

As shown in FIGS. 15a to 15f, the bottom cap 240 comprises a base section 241, a mid-section 242, and top section 243. The top section 243 forms the first end of the bottom cap and has a diameter that is substantially equal to that of the mid-section 242. A peripheral wall 246 extends around the periphery of a first surface 245 of the top section 243 and projects above the first surface. In the embodiment shown in FIGS. 14a to 14f, the peripheral wall is broken at two opposing points to form a pair of opposing slot-like openings 247 in the wall. The second end of the bob fits snugly within the space above the first surface of the top section and defined by the peripheral wall.

A frustoconical recess 248 is formed in the centre of the first surface and is bisected by a slot 249. The frustoconical recess 248 substantially corresponds with the frustoconical tip 236 of the bob. However, the frustoconical recess 248 is deeper than the tip 236 of the bob is long, which creates a void between the tip of the bob and the first surface of the bottom cap. The receiving slot 249 prevents fluid from being trapped in the void and isolated beneath the bob.

The base section 241 of the bottom cap is substantially cylindrical and has a diameter larger than that of the mid-section, so that a portion of the base section forms a lip 244 that extends beyond the circumferential periphery of the mid-section 242. A channel 245 extends around the circumference of the bottom cap and delineates the base section from the mid-section. The channel is adapted to receive a seal, such as an o-ring 11 therein, as shown in FIGS. 10 and 11c.

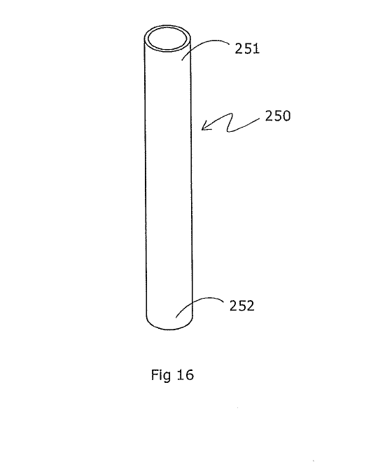

FIG. 16 shows the outer tube 250 having open first and second ends 251, 252. The bob 230 is positioned substantially concentrically within the outer tube and the outer tube is attached to the cell coupler at its first end 251 and to the bottom cap at Its second end 252. The second end 252 of the outer tube abuts the lip 244 of the bottom cap and the o-ring 11 presses against the interior surface of the outer tube to attach and seal the tube to the bottom cap. The outer tube is preferably transparent to allow for bubbles to be identified and removed when the sample is loaded in the cell. The tube may be glass or plastic.

In this arrangement, a cavity 260 is formed between the outer surface of the bob and the outer tube, as shown in FIG. 11c. The cavity is adapted to hold a sample for rheological analysis. The receiving slot 249 formed in the first surface of the bottom cap and the slot-like openings 247 in the peripheral wall of the bottom cap provide a fluid pathway from the void beneath the bob to the cavity 260. This allows for the sample material fluid to expand due to heating and prevents gas bubbles from being trapped during the Initial set-up.

In this arrangement, the outer tube, bottom cap, bob, and spindle form an enclosed cell within which a sample material can be held. The bob is able to rotate clockwise and anti-clockwise, as desired, to subject the sample to shear forces. The outer surface of the bob forms the inner wall of the cell and the outer tube forms the outer wall of the cell.

Typically, in use, the bottom cap would be pushed onto the second end of the outer tube, as described above. The outer tube would then be filled with the desired quantity of a sample material and the first end of the tube would then be pushed over the second end of the cell coupler so that the second end of the spindle and the bob are positioned concentrically within the outer tube. The cylindrical Couette cell is then attached to the drive shaft unit described above.

In this arrangement, the drive shaft (the primary shaft and extension shaft), spindle, and bob extend along the same axis in a substantially linear arrangement. Each of these component parts are attached together so that rotation of the primary shaft by the motor, causes the drive shaft extension, spindle, and bob to rotate simultaneously, at the same rotational speed, and in the same direction to at least minimise or substantially eliminate mechanical backlash.

The rotation of the bob within the outer tube of the analysis device causes shear forces to be imparted on the sample material held within the device. The response of the sample material to these forces can be analysed with rheo-NMR techniques.

### Rotating Outer Wall Cylindrical Couette Cell

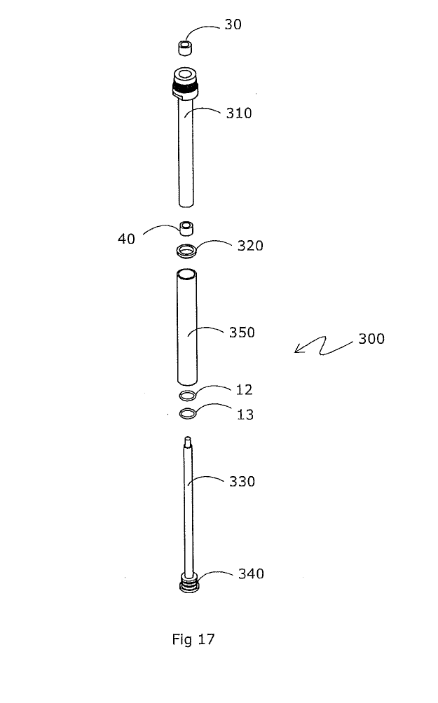

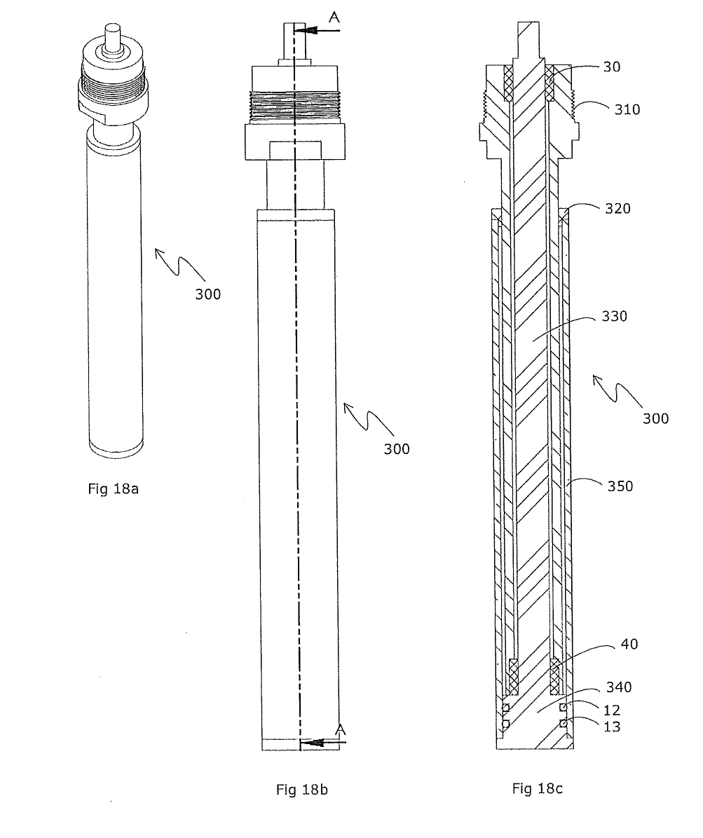

Another form of analysis device that can be attached to the drive shaft unit is a rotating outer wall cylindrical Couette cell 300, as shown In FIG. 17. The rotating outer wall cell 300 comprises a cell coupler 310, an alignment collar 320, a spindle 330, a bottom cap 340, and an outer tube 350, as shown in FIGS. 17 and 18a to 18c.

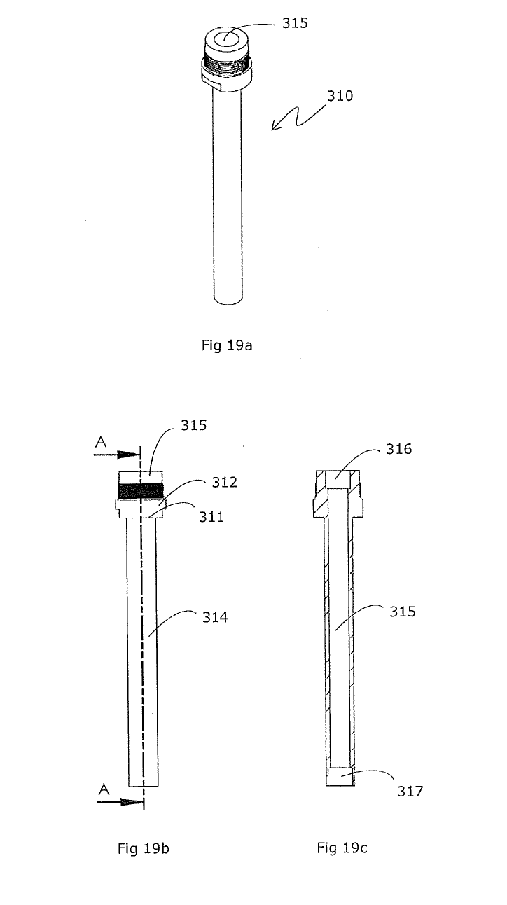

As shown in FIGS. 19a to 19c, the cell coupler 310 comprises a body 311 having a collar 312 that extends around the circumference of the body. A first end 313 of the cell coupler projects from the collar and has a threaded section for meshing with the second end 162 of the extension housing to attach the cell coupler to the extension housing, as described above. In this way, the cell coupler attaches the rotating outer wall cylindrical Couette cell to the drive shaft unit.

In one form, the cell coupler comprises gripping surfaces that a wrench or the like can grip onto when attaching and detaching the cell to and from the drive shaft unit.

The cell coupler also comprises a second end 314 that extends from the opposite end of the cell coupler body 311 and is positioned substantially concentrically within the outer tube 350. The outer surface of the second end of the cell coupler forms an inner wall of the rotating outer wall Couette cell and the outer tube forms the outer wall, as shown in FIGS. 19a to 19c. However, in other forms, the inner wall may comprise a tube that is formed separately from the cell coupler and that is attached to the cell coupler by any other suitable way of attachment, such as by attaching the tube to a projecting second end of the cell coupler using complementary threaded surfaces or using an arrangement of apertures and an engaging screw or the like, as described above.

A centrally located bore 315 extends along the length of the cell coupler and substantially aligns with the central bore of the extension housing when the analysis device is attached to the drive shaft unit. The spindle 330 is positioned substantially concentrically within the central bore 315 of the cell coupler. The spindle comprises an elongate cylindrical body 331 having a first end 332 that attaches to the second end of the extension shaft via an in line coupling or the like. The spindle also comprises an opposing second end 333 that is attached to the bottom cap 340. The central bore 315 of the cell coupler may be adapted to house bushes or bearings that engage with the spindle to keep the spindle aligned with the extension shaft. In one form, the diameter of the bore 315 is larger at Its ends than the diameter of the middle region so that a first internal collar 316 is formed at the first end of the cell coupler and a second internal collar 317 is formed at the second end of the cell coupler. The internal collars 316, 317 are adapted so that a bush 30, 40 can fit within each collar 316, 317 respectively to maintain the concentric alignment of the spindle 330 within the bore 315 and to help the spindle to rotate freely within the cell coupler.

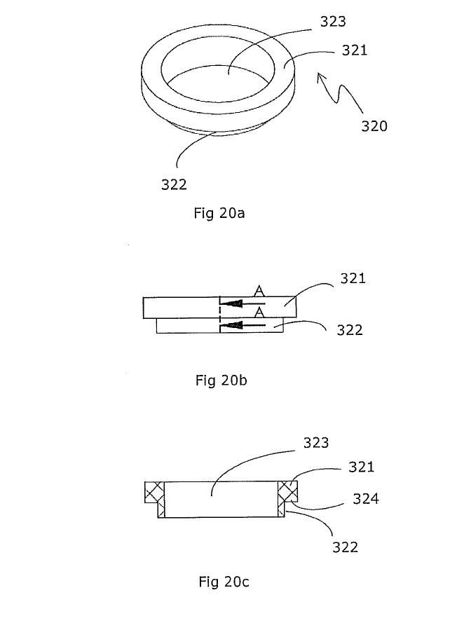

A ring shaped alignment collar 320 fits around the circumference of the cell coupler and is used to position the outer tube in relation to the cell coupler. The alignment collar comprises a first end 321, an adjacent second end 322, and a central bore 323 extending between, as shown in FIGS. 20a to 20c. The second end of the cell coupler is received within the bore of the alignment collar. The diameter of the first end of the alignment collar is larger than that of the second end, so that the first end forms an outwardly projecting lip 324 that abuts a first end 351 of the outer tube 350. The alignment collar 320 is adapted to position the second end of the cell coupler substantially concentrically within the outer tube and to allow the outer tube to rotate freely with respect to the alignment collar.

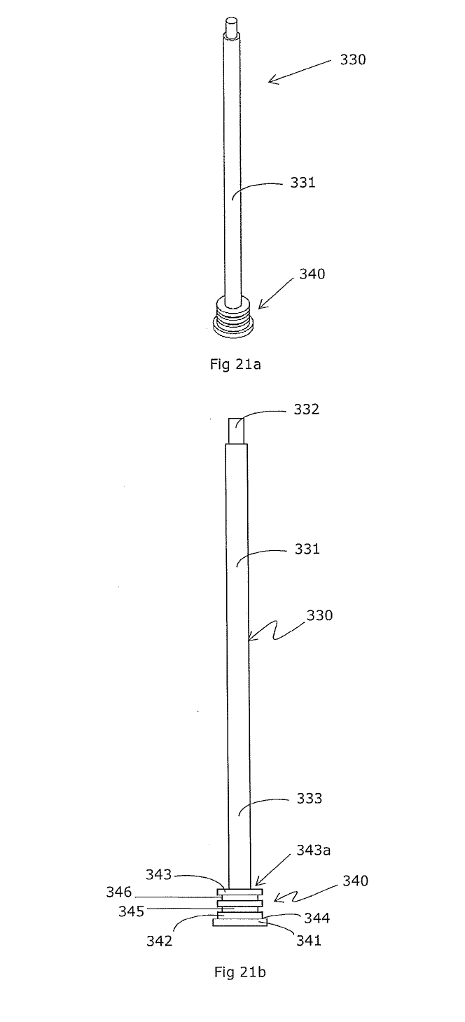

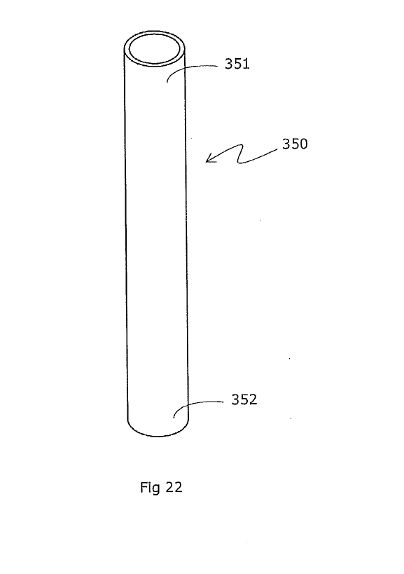

The bottom cap 340 attaches to a second end of the outer tube 350. In one form, the bottom cap comprises a base section 341, a mid-section 342, and a top section 343, as shown in FIGS. 21a and 21b. In the embodiment shown, the spindle is mounted to an upper surface 343a of the top section 343 (also the first end of the bottom cap) and the bottom cap 340 is Integral with the spindle 330. However, in other forms, the second end of the spindle may be adapted to attach to a separately formed bottom cap.

The base section 341 of the bottom cap is substantially cylindrical and has a diameter larger than that of the mid-section to form a lip 344 that extends beyond the periphery of the mid-section 342. The diameter of the top section is substantially equal to that of the mid-section. A second end 352 of the outer tube 350 fits over the top and mid-sections of the bottom cap and abuts the projecting lip 344 of the bottom cap. In this arrangement, the end face of the second end of the cell coupler abuts the upper surface 343a of the top section of the bottom cap 340.

A channel 345 extends around the circumference of the mid-section of the bottom cap. A further circumferential channel 346 separates the mid-section from the top section. A seal, such as an o-ring 12, 13 is located in each of the circumferential channels 345, 346 respectively, as shown in FIGS. 18a and 18c, to attach and seal the bottom cap against the second end of the outer tube. However, it is envisaged that the bottom cap and outer tube may be attached in any suitable manner. For example, the outer tube may be screwed onto the bottom cap.

The outer tube is preferably transparent to allow for bubbles to be identified and removed when the sample is loaded in the cell. The tube may be glass or plastic.

The outer tube has a larger diameter than that of the second end of the cell coupler so that a cavity is formed between the inner and outer walls of the Couette cell. The cavity is of a sufficient size to hold a sample material therein.

In this arrangement, as the motor causes the drive shaft (primary shaft and extension shaft) to rotate, the spindle and bottom cap are also caused to rotate. Because the outer tube is sealed against the bottom cap, the outer tube is caused to rotate. In this way, rotation of the drive shaft causes the outer tube to rotate simultaneously, at the same rotational speed, and in the same direction.

Because the inner wall of the Couette cell is attached to the non-moving extension housing, the inner wall remains stationary in use.

Due to the curvature of the walls of a cylindrical Couette cell, the sample material exhibits a stress variation across the cavity, which can be analysed using rheo-NMR. The rotating outer wall cylindrical Couette cell decouples the high curvature inner wall from the moving surface and provides different rheological phenomena.

### Cone/Plate-Plate Device

Other forms of analysis device that can be attached to the drive shaft unit to form a rheology unit are a cone-plate and a plate-plate analysis device. Each device comprises substantially the same parts, except that the upper plate of the plate-plate device is replaced with a cone in the cone-plate device.

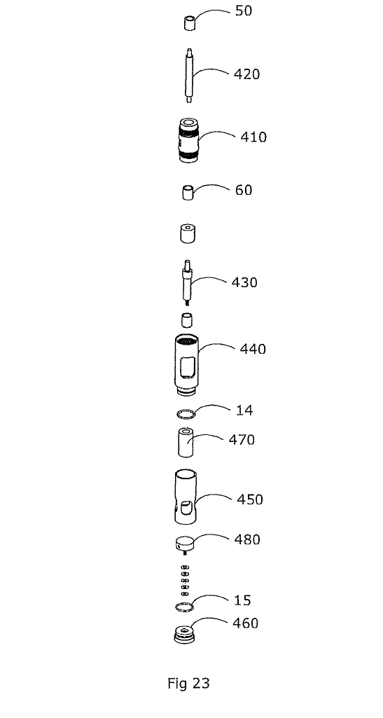

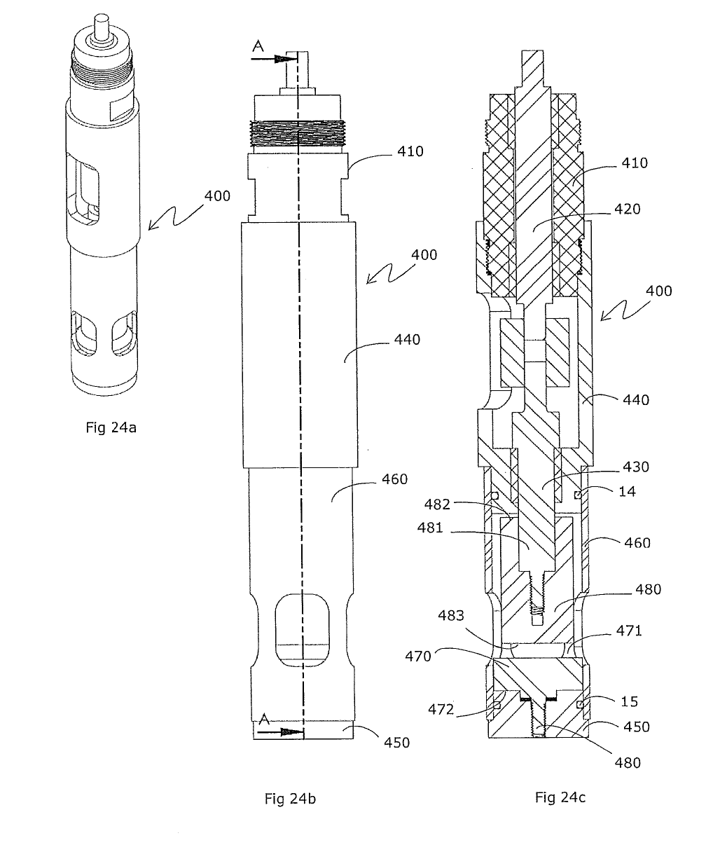

One form of plate-plate analysis device 400 is shown in FIGS. 23 and 24a to 24c. The plate-plate analysis device 400 comprises a cell coupler 410, a coupler shaft 420, a spindle 430, a top cap 440, an outer tube 450, a bottom cap 460, an upper plate 470, and a lower plate 480.

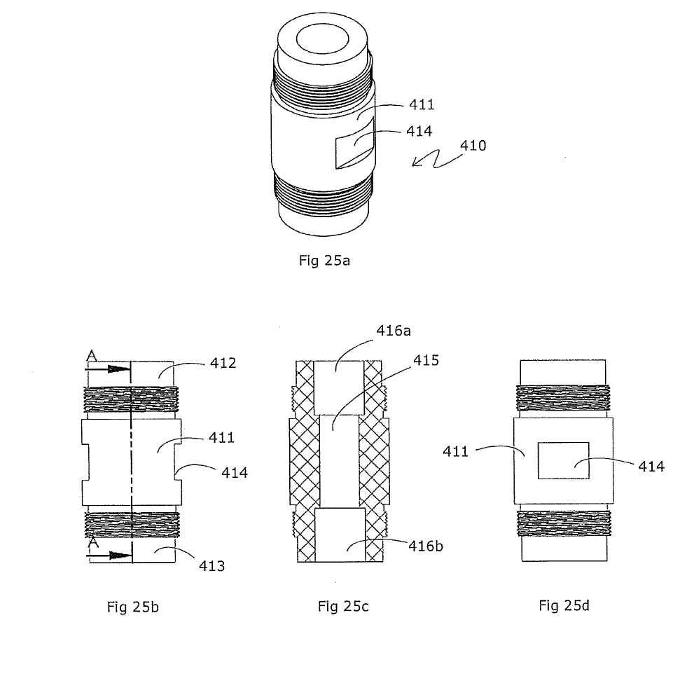

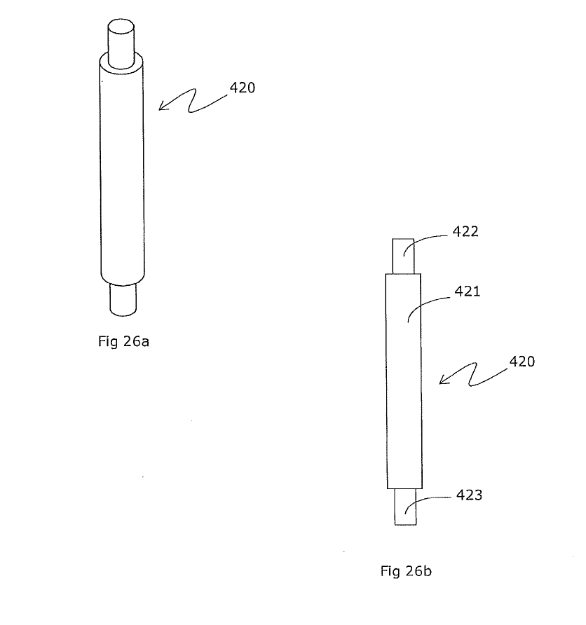

As shown in FIGS. 25a to 25d, the cell coupler 410 comprises a body 411, a first end 412, and a second end 413. The first end 412 projects from the body and has a threaded section for meshing with the threaded second end of the extension housing, as described above, to attach the analysis device to the extension housing. The second end 413 of the cell coupler extends from the opposite end of the coupler body 411 and comprises a threaded section that meshes with a threaded portion of a central bore 442 of the top cap 440 to attach the cell coupler to the top cap, as shown in FIG. 24c. In this arrangement, the top cap is substantially in line with the cell coupler and the central bore 415 of the cell coupler aligns with the central bore of the top cap.

In a preferred form, as shown in FIGS. 25a to 25d, gripping surfaces 414 are provided on opposing sides of the coupler body. In one form, the gripping surfaces are substantially flat regions formed on the cylindrical coupler body that a wrench or the like can grip onto when attaching and detaching the cell to and from the drive shaft unit. In other forms, the gripping surfaces may be textured regions or may be of any other form that helps a person or device to grip the analysis device.

A central bore 415 extends along the length of the cell coupler and substantially aligns with the central bore of the extension housing when the analysis device is attached to the drive shaft unit.

When performing traditional rheology experiments on commercial rheometers, a cone-plate or plate-plate analysis device would have a gap of approximately 1 mm between the cone and plate, or between the two plates, as the case may be. To perform analogous experiments within an NMR magnet, the fluid filling the gap would need to centred within the RF coil of the magnet. To accomplish this goal and to maintain the precise alignment of all rotating parts, the cone/plate-plate device includes a coupler shaft 420, which acts as an additional extension to the drive shaft.

As shown in FIGS. 24a and 24b, the coupler shaft 420 comprises a body 421, a first end 422, and a second end 423. The first end of the coupler shaft is adapted to engage with the second end of the extension shaft via an in line coupling or the like. The second end of the coupler shaft projects from the second end of the cell coupler and is attached to the spindle 430, via an in line coupling or the like. To keep the coupler shaft concentrically positioned within the cell coupler and aligned with the extension shaft, the central bore 415 of the cell coupler may comprise bushes or bearings that engage with the coupler shaft and keep the coupler shaft aligned. For example, in one form, the bore 415 of the cell coupler comprises a first internal collar 416a located at the first end of the cell coupler within which a bush 50 is located. A second internal collar 416b is located in the bore 415 at the second end of the cell coupler, Another bush 60 is located within the second internal collar. The bushes 50, 60 keep the coupler shaft in the correct, aligned and concentrically located position and also help the coupler shaft to rotate smoothly within the cell coupler.

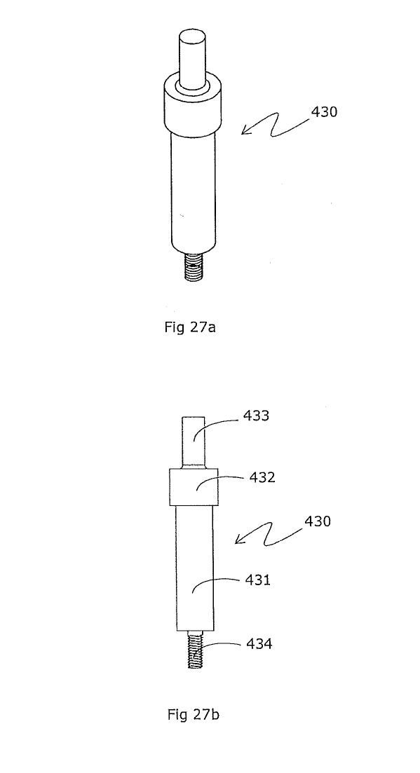

One form of spindle 430, as shown in FIGS. 27a and 27b, comprises a substantially cylindrical body 431 having a collar 432 that extends around the circumference of the body 431. A first end 433 of the spindle projects from the collar 432 and attaches to the second end 423 of the coupler shaft 420, as described above. A second end 434 of the spindle extends from the opposing end of the spindle body and is attached to the upper plate 470 (or to a cone if the device is to be converted to a cone-plate analysis device). In one form, the second end 434 of the spindle is threaded and meshes with a threaded portion of a central bore 471 of the upper plate/cone.

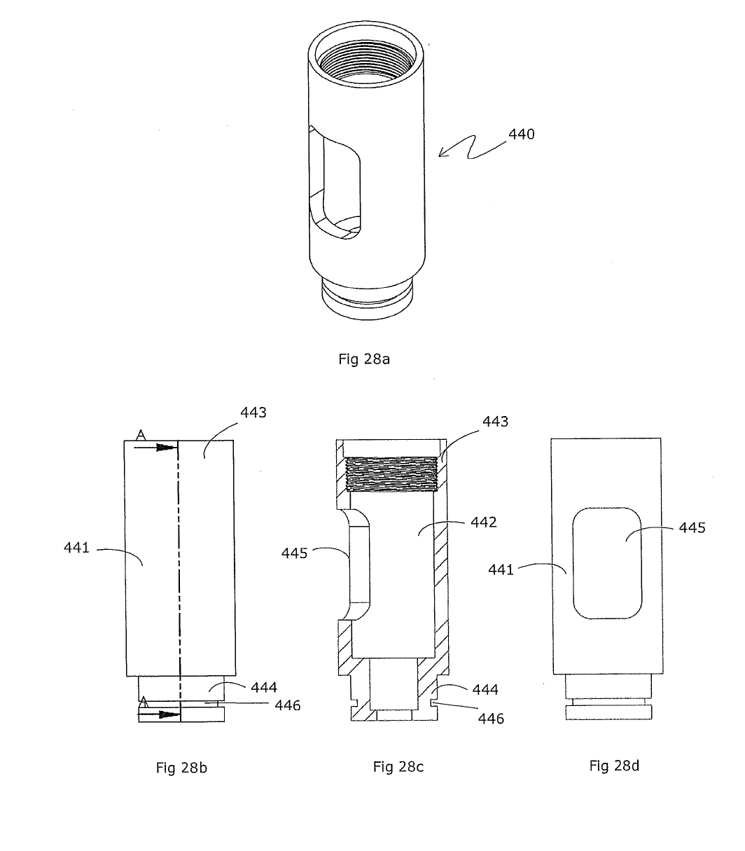

The spindle 430 is substantially concentrically located within a central bore 442 of the top cap 440, as shown in FIG. 24c. The top cap comprises a substantially cylindrical body 441 having a first end 443 and an opposing second end 444, as shown in FIGS. 28a to 28d. A portion of the bore of the top cap is threaded at the first end and meshes with the threaded second end 413 of the cell coupler, to form a threaded connection, as described above. An access aperture 445 may be formed in the top cap body 441 to provide access to fasteners, such as screws, and the couplings nearby.

A channel 446 extends around the circumference of the second end 444 of the top cap within which a seal, such as an o-ring 14 is positioned. The second end of the top cap fits within a first end of the outer tube 450 and the o-ring 14 presses against the interior surface of the outer tube to attach and seal the top cap to the outer tube.

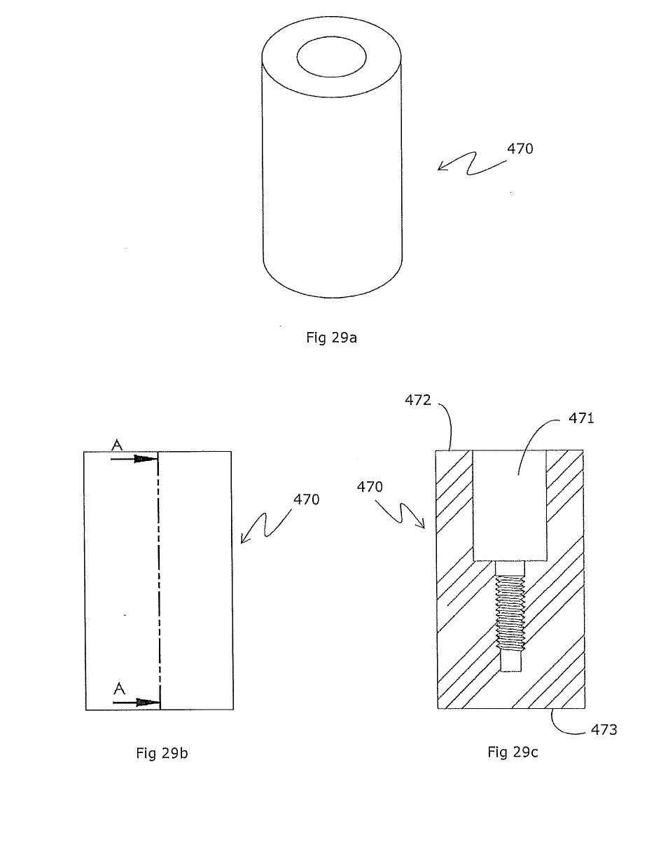

As shown in FIGS. 29a to 29c, the upper plate 470 comprises an upper surface 472 and a central bore 471 formed in the upper surface. At least a portion of the central bore has a threaded surface. As described above, the threaded second end 434 of the spindle meshes with the threaded bore 471 to attach the spindle to the upper plate. The central bore 471 has a closed end so that the upper plate is provided with a substantially flat, solid bottom surface 473.

To provide a cone-plate analysis device, the upper plate is replaced with a cone (not shown), having a conical bottom surface.

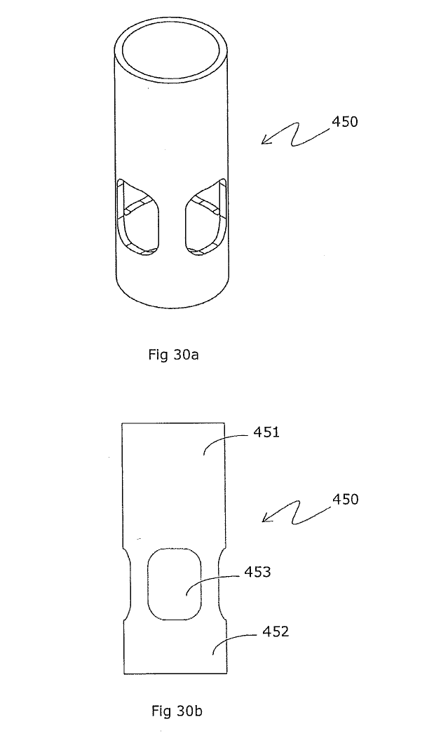

The upper plate is positioned within the outer tube 450. One form of outer tube 450 is shown in FIGS. 30a and 30b. The outer tube is typically transparent and may be made of plastic or glass. The first end 451 of the outer tube 450 attaches to the top cap, as described above. An opposing second end 452 of the outer tube is attached to the bottom cap 460. One or more access apertures 453 may be located around the periphery of the outer tube 450 to allow access to a sample that will be held in the interior of the outer tube when the analysis device is in use.

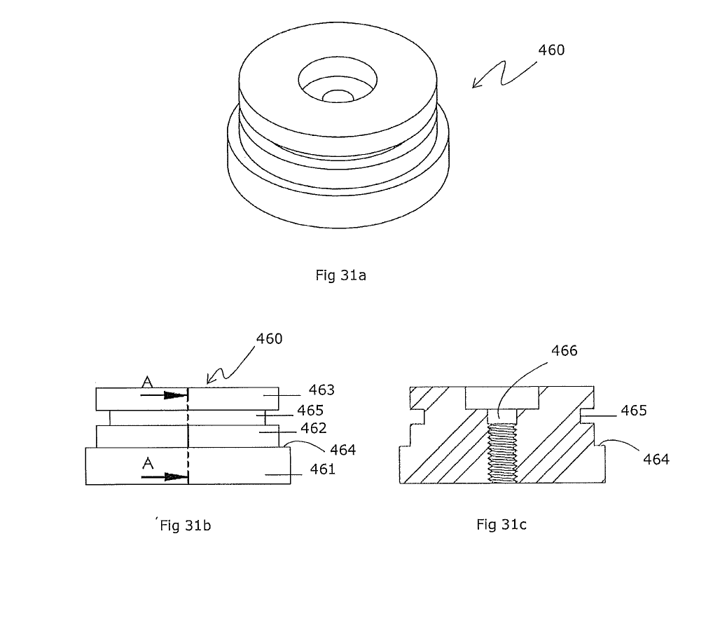

The second end of the outer tube is attached to the bottom cap 460. In one form, the bottom cap comprises a base section 461, a mid-section 462, and a top section 463, as shown in FIGS. 31a to 31c. In one form, the top section comprises a first surface in which a threaded central bore 466 is located. The base section 461 is substantially cylindrical and has a diameter larger than that of the mid-section to form a lip 464 that extends beyond the periphery of the mid-section 462. The diameter of the top section is substantially equal to that of the mid-section. The second end of the outer tube fits over the top section and mid section and abuts the lip 464 of the bottom section. A channel 465 extends around the circumference of the bottom cap and separates the mid-section from the top section. An o-ring 15 is located in the channel 465, as shown in FIGS. 23 and 24c, and presses against the inner surface of the outer tube to attach and seal the bottom cap to the outer tube.

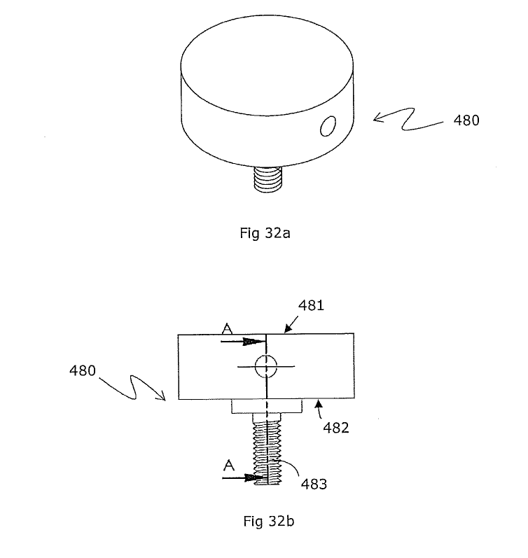

In one form, the lower plate 480 attaches to the bottom cap 460. As shown in FIGS. 32a and 32b, the lower plate 480 comprises an upper surface 481 and a bottom surface 472. The upper surface is substantially flat and is adapted to lie horizontally. The upper surface of the lower plate is spaced apart from the upper plate/cone so that a cavity is formed between the two plates (or between the cone and plate, as the case may be).

A threaded attachment shaft 483 extends from the bottom surface of the lower plate and meshes with the threaded central bore 466 of the bottom cap by screwing the lower plate 480 to the bottom cap 460. In other forms, the top section 463 of the bottom cap comprises a substantially flat upper surface that forms the lower plate.

Spacers can be used between the lower plate and bottom cap to modify the height of the cavity between the upper plate/cone and the lower plate.

Each of the component parts of the rheology unit are coupled together in a manner that at least minimises or substantially eliminates mechanical backlash as the motor rotates. Therefore, as the motor causes the drive shaft (primary shaft and extension shaft) to rotate, the coupler shaft, spindle, and upper plate/cone will also rotate simultaneously at the same speed and in the same direction. The lower plate supports the sample material and remains stationary.

In use, a sample material is placed on the lower plate in the cavity formed between the lower and upper plates or between the lower plate and cone, as the case may be. The lower plate is accessed via the access apertures formed in the outer tube. The analysis device is attached to the drive shaft unit, as described above, to form a rheology unit. The device can be attached to the drive shaft unit before or after the sample material is placed on the lower plate. The rheology unit is a substantially cylindrical elongate unit that fits in the magnet bore of an NMR machine for rheo-NMR experiments.

### Advantages

Any of the analysis devices described above can be attached to the drive shaft unit to form a substantially cylindrical rheology unit for fitting within the RF coil and imaging system of a wide bore superconducting magnet of an NMR machine. Each analysis device can be mounted directly to the drive shaft unit prior to loading the rheology unit into the NMR machine.

By attaching the analysis device to the drive shaft unit before placing the rheology unit within the bore of an NMR machine, it is possible to align the analysis device and drive shaft precisely and to establish a firm connection between the component parts of the rheology unit. This helps to eliminate or at least minimise mechanical backlash.

Because the rheology unit of the invention minimises or substantially avoids mechanical backlash, and because the unit can operate under oscillatory motion, the rheology unit of the invention can be used to generate a wide range of shear profiles not currently possible with prior art devices.

The invention also makes it possible to align rheo-NMR experiments with traditional rheology techniques to further expand the range of possible shear profiles obtainable. In particular, it is possible to use the rheology unit for large amplitude oscillatory shear experiments. It is also possible to accomplish oscillatory motion and other advanced motion profiles (such as those that occur during the start up phase) using the rheology unit of the invention by using a stepper motor, a programmable control system, and a position sensor, such as a high resolution optical encoder to vary the rotational frequency, speed and/or direction of the drive shaft during experiments.

Where the rheology unit of the invention allows the motor and control system to adjust the speed, frequency of rotation, and/or direction of rotation of the drive shaft to achieve pre-programmed parameters in response to feedback received from an optical encoder mounted on the motor, a greater range of experiments can be undertaken using the invention and greater control of the shear profiles is possible.

In addition, the drive shaft unit of the invention allows for analysis devices (such as shear cells) having different geometries to be attached to the same drive shaft unit so that sample materials can be measured under a variety of conditions.

Although the invention has been described by way of example, it should be appreciated that variations and modifications may be made without departing from the scope of the invention as defined in the claims. Furthermore, where known equivalents exist to specific features, such equivalents are incorporated as if specifically referred in this specification.

For example, although a two part drive shaft and two part drive shaft housing have been described above, the rheology unit of the invention could alternatively comprise a single part drive shaft located within a single part drive shaft housing. To reduce the effect of flex of the drive shaft, the shaft is precision engineered and is located substantially concentrically within the drive shaft housing using bushes or bearings. The first and second ends of the drive shaft are attached to the motor and analysis device respectively using inline couplings or the like, as described above. As above, the first end of the drive shaft housing supports the motor mount and the second end of the drive shaft housing is threaded to mesh with the threaded first end of a cell coupler of an analysis device. Therefore, the drive shaft used in the invention may be a single part drive shaft or a series of substantially aligned drive shafts, such as the two part drive shaft shown in the drawings. Similarly, the drive shaft housing used in the invention may be a single part housing or a series of subtantially aligned drive shaft housings. In both forms, the drive shaft and drive shaft housing are adapted to attach the drive shaft unit to an analysis device using a threaded connection that at least minimises or eliminates mechanical backlash.

Furthermore, although preferred forms of the invention have been described in which one or more parts of the invention are described as fitting within the central bore of one or more other parts of the invention, it should be appreciated that the reverse arrangement could be used without departing from the scope of the invention. For example, although the bottom cap of the attachment devices has been described as having a portion that fits within the outer tube, the bottom cap and outer tube may alternatively be modified so that the outer tube fits within a bore or collar formed in the bottom cap. Similarly, although one or more parts of the invention are adapted to be sealed against one or more other parts by having at least one channel for receiving an o-ring therein, it is envisaged that these parts could be adapted in any other appropriate way to provide the required attachment and/or seal, as would be understood by a person skilled in the art. For example, two parts may be screwed together using screws or by screwing a threaded region of one part onto a threaded region of another part.

In addition, although the invention has been described and illustrated as having the motor at the top of the rheology unit and the analysis device at the bottom, it is envisaged that in other forms of the invention, the analysis device is located at the top of the rheology unit and the motor is located at the bottom of the unit. In this arrangement, the rheology unit can be fed into an NMR machine from the bottom of the machine.

1. A rheology unit having a drive shaft unit comprising:
a two part drive shaft comprising a primary shaft having a first end and a second end, and an extension shaft having a first end and a second end, the first end of the
extension shaft being coupled to the second end of the primary shaft; a two part drive shaft housing for housing the drive shaft, the drive shaft housing comprising a primary housing having a first end and a second end and an extension housing also having a first end and a second end, wherein the first end of the extension housing is attached to the second end of the primary housing;
a motor for rotating the drive shaft within the drive shaft housing;
a positioning sensor for sensing the position of the drive shaft relative to the drive shaft housing; and
a control system for controlling the speed, frequency, and/or direction of rotation of the drive shaft;
wherein the extension shaft is concentrically supported within the extension housing and the extension housing is adapted to attach to an analysis device through a threaded connection that allows the analysis device to substantially align with the drive shaft housing.

2. The rheology unit of claim 1, wherein the motor is a servo-stepper motor that is connected to the first end of the drive shaft.

3. The rheology unit of claim 1, wherein the positioning sensor is an optical encoder.

4. The rheology unit of claim 1, wherein the drive shaft unit is attached to an analysis device for holding a sample material to be analysed in rheo-NMR experiments.

5. The rheology unit of claim 4, wherein the analysis device comprises a cell coupler adapted to attach the analysis device to the drive shaft unit, the cell coupler having a threaded first end that meshes with a threaded second end of the extension housing.

6. The rheology unit of claim 5, wherein the analysis device comprises a spindle that is coupled to the extension shaft to cause the spindle and extension shaft to rotate simultaneously.

7. The rheology unit of claim 5, wherein the analysis device is any one of: a cylindrical Couette cell; a rotating outer wall Couette cell; a cone-plate shear cell; and a plate-plate shear cell.

8. An analysis device configured to attach to the drive shaft of the rheology unit of claim 1, the device comprising a cell coupler having a threaded first end that meshes with a threaded second end of the extension housing to attach the analysis device to the drive shaft unit.

9. The analysis device of claim 8, wherein the device comprises a cylindrical Couette cell further comprising a spindle, a bob, a bottom cap, and an outer tube, wherein the spindle is adapted to attach the bob to the drive shaft of the drive shaft unit and wherein the bob is positioned substantially concentrically within the outer tube, which comprises a first end that is attached to the cell coupler and a second end that aligns with the bottom cap, wherein a cavity is formed between the bob and the outer tube within which a sample material may be held.

10. The analysis device of claim 8, wherein the device comprises a rotating outer wall Couette cell comprising an inner wall and an outer wall and a gap between the inner and outer walls for holding a sample material therein, wherein the outer wall is adapted to rotate when the analysis device is attached to the drive shaft unit of the rheology unit.

11. The analysis device of claim 10, wherein the rotating outer wall Couette cell further comprises a spindle, a bottom cap, and an outer tube, wherein the inner wall is formed by a second end of the cell coupler and the outer wall is formed by the outer tube, wherein a first end of the spindle is connected to the drive shaft to rotate the spindle and a second end of the spindle is attached to the bottom cap, and wherein a second end of the outer tube is also attached to the bottom cap to cause the outer tube to rotate simultaneously with the drive shaft.

12. The analysis device of claim 11, wherein the rotating outer wall Couette cell further comprises an alignment collar attached to the cell coupler and adapted to position the second end of the cell coupler concentrically within the outer tube.

13. The analysis device of claim 8, wherein the analysis device comprises a cone-plate shear cell, the shear cell further comprising a coupler shaft and a spindle, the coupler shaft being adapted to attach the spindle to the drive shaft of the drive shaft unit, an outer tube within which the spindle is concentrically located, the outer tube comprising a first end attached to a top cap attached to the cell coupler and a second end attached to a bottom cap, wherein the device further comprises a lower plate supported by the bottom cap, and a cone that is attached to the spindle to rotate simultaneously with the drive shaft.

14. The analysis device of claim 8, wherein the analysis device comprises a plate-plate shear cell, the shear cell further comprising a coupler shaft and a spindle, the coupler shaft being adapted to attach the spindle to the drive shaft of the drive shaft unit, an outer tube within which the spindle is concentrically located, the outer tube comprising a first end attached to a top cap attached to the cell coupler and a second end attached to a bottom cap, wherein the device further comprises a lower plate supported by the bottom cap, and an upper plate that is attached to the spindle to rotate simultaneously with the drive shaft.
